(19) United States
(12) Patent Application Publication
(10) Pub. No.: US 2011/0168435 A1
(43) Pub. Date: Jul. 14, 2011

(54) PRINTED CIRCUIT BOARD

(75) Inventors: ALAN L. BARRY, TORRANCE, CA (US); ELI B. SMITH, BELLFLOWER, CA (US); BROOKS S. MANN, REDONDO BEACH, CA (US); NICHOLAS HAYDEN HERRON, REDONDO BEACH, CA (US); MARK D. KORICH, CHINO HILLS, CA (US); DAVID TANG, FONTANA, CA (US); CINDY CHOU, LAKEWOOD, CA (US)

(73) Assignee: GM GLOBAL TECHNOLOGY OPERATIONS, INC., DETROIT, MI (US)

(21) Appl. No.: 12/686,775

(22) Filed: Jan. 13, 2010

(51) Int. Cl. H05K 1/09; H05K 1/00

(52) U.S. Cl. 174/257; 174/250

(57) ABSTRACT

A printed circuit board includes, but is not limited to, a plurality of electrically conductive layers and a plurality of dielectric layers. Each dielectric layer is interposed between adjacent conductive layers to form a body of alternate conductive layers and dielectric layers. At least one of the electrically conductive layers protrudes beyond an end of the body.

### STATEMENT REGARDING FEDERALLY SPONSORED RESEARCH OR DEVELOPMENT

This invention was made with Government support under DE-FC26-07NT43123, awarded by the Department of Energy. The Government has certain rights in this invention.

### TECHNICAL FIELD

The technical field generally relates to printed circuit boards.

### BACKGROUND

Printed circuit boards conventionally include multiple electrically conductive layers interleaved with multiple dielectric layers. Each electrically conductive layer is typically formed into one or more pathways (known as traces) to provide a path for an electric current. Electronic components are attached to the printed circuit board and electrically connected to the traces.

During the process of fabricating a printed circuit board, the electrically conductive layers initially completely cover one or both sides of a dielectric layer. Portions of the electrically conductive layers are then removed from the dielectric layer. The portions of the electrically conductive layer that remain comprise the traces.

The removal of portions of the electrically conductive layers may be accomplished by using an acid to etch away the unwanted portions. The process includes placing a protective covering over the portions of the electrically conductive layer that are to remain on the dielectric layer and then applying the acid across the entire surface of the electrically conductive layer. The acid dissolves the exposed portions of the electrically conductive material and the remaining structure (i.e., the dielectric layer and the traces) is then adhered in a sandwich-like fashion to one or more similar structures using a dielectric glue to form a body having an alternate arrangement of electrically conductive layers and dielectric layers. This process may be repeated until a desired number of electrically conductive layers have been assembled.

Some printed circuit boards, such as those used in insulated-gate bipolar transistors, need to carry relatively high currents. The higher the current, the thicker the electrically conductive pathway needs to be. Printed circuit boards that are designed to carry high currents typically include one or more electrically conductive layers having a greater thickness than the other electrically conductive layers in the body. Because of existing limitations inherent in the known methods of printed circuit board fabrication, these thickened layers are not positioned on the outer surfaces of the printed circuit board but are instead disposed internally within the printed circuit board. Because of their internal location, connecting these thickened layers to leads and/or wires that carry the high current can be challenging.

Conventionally, via holes are utilized to connect leads and/or wires to the thickened layers. Via holes are relatively small holes that extend either partially or entirely through the printed circuit board. The via holes are plated or otherwise coated with an electrically conductive material to electrically connect the electrically conductive layer on the surface of the printed circuit board to any and/or all of the other electrically conductive layers sandwiched within the printed circuit board. However, because a single via hole is not designed and/or constructed to carry high current, multiple via holes are needed to carry high current to the thickened electrically conductive layers located within the body. The positioning of multiple via holes through the printed circuit board, however, is expensive and can greatly complicate the design and fabrication of the printed circuit board.

Accordingly, it is desirable to avoid the use of complicated designs in order to access internal layers of a printed circuit board. Furthermore, other desirable features and characteristics will become apparent from the subsequent detailed description and the appended claims, taken in conjunction with the accompanying drawings and the foregoing technical field and background.

### SUMMARY

Multiple embodiments of a printed circuit board are disclosed herein. In a first, non-limiting embodiment, the printed circuit board includes, but is not limited to, a plurality of electrically conductive layers and a plurality of dielectric layers. Each dielectric layer is interposed between adjacent conductive layers to form a body of alternate conductive layers and dielectric layers. At least one of the electrically conductive layers protrudes beyond an end of the body.

In a second non-limiting embodiment, the printed circuit board includes, but is not limited to, a plurality of electrically conductive layers and a plurality of dielectric layers. Each dielectric layer is interposed between adjacent electrically conductive layers of the plurality of electrically conductive layers to form a body of alternate electrically conductive layers and dielectric layers. Two neighboring electrically conductive layers internal to the body protrude beyond an end of the body.

In a third non-limiting embodiment, the printed circuit board includes, but is not limited to, a plurality of electrically conductive layers and a plurality of dielectric layers. Each dielectric layer is interposed between adjacent electrically conductive layers of the plurality of electrically conductive layers to form a body of alternate electrically conductive layers and dielectric layers. A first non-electrically conductive opening extends from a first surface of the body to a first electrically conductive layer internal to the body.

### DESCRIPTION OF THE DRAWINGS

One or more embodiments will hereinafter be described in conjunction with the following drawing figures, wherein like numerals denote like elements, and

FIG. 1 is a perspective view schematically illustrating a printed circuit board made in accordance with the teachings of the present disclosure;

FIG. 2 is a schematic cross-sectional view of the printed circuit board of FIG. 1;

FIG. 3 is a schematic cross-sectional view of an alternate embodiment of the printed circuit board of FIG. 1;

FIG. 4 is a schematic cross-sectional view of another alternate embodiment of the printed circuit board of FIG. 1; and

FIG. 5 is a schematic cross-sectional view of yet another alternate embodiment of the printed circuit board of FIG. 1.

### DETAILED DESCRIPTION

The following detailed description is merely exemplary in nature and is not intended to limit application and uses. Furthermore, there is no intention to be bound by any expressed or implied theory presented in the preceding technical field, background, brief summary or the following detailed description.

A printed circuit board is disclosed herein that facilitates the transmission of electric current directly to electrically conductive layers that are situated internally within the sandwich-like structure of the printed circuit board without the use of electrically conductive via holes. In at least one embodiment, one or more layers of the printed circuit board are removed to expose one or more internally situated conductive layers such that the internally situated conductive layers are easily accessible and permit the direct attachment of leads, wires and/or electrical connectors. A greater understanding of the examples of printed circuit board disclosed herein may be obtained through a review of the illustrations accompanying this application together with a review of the detailed description that follows.

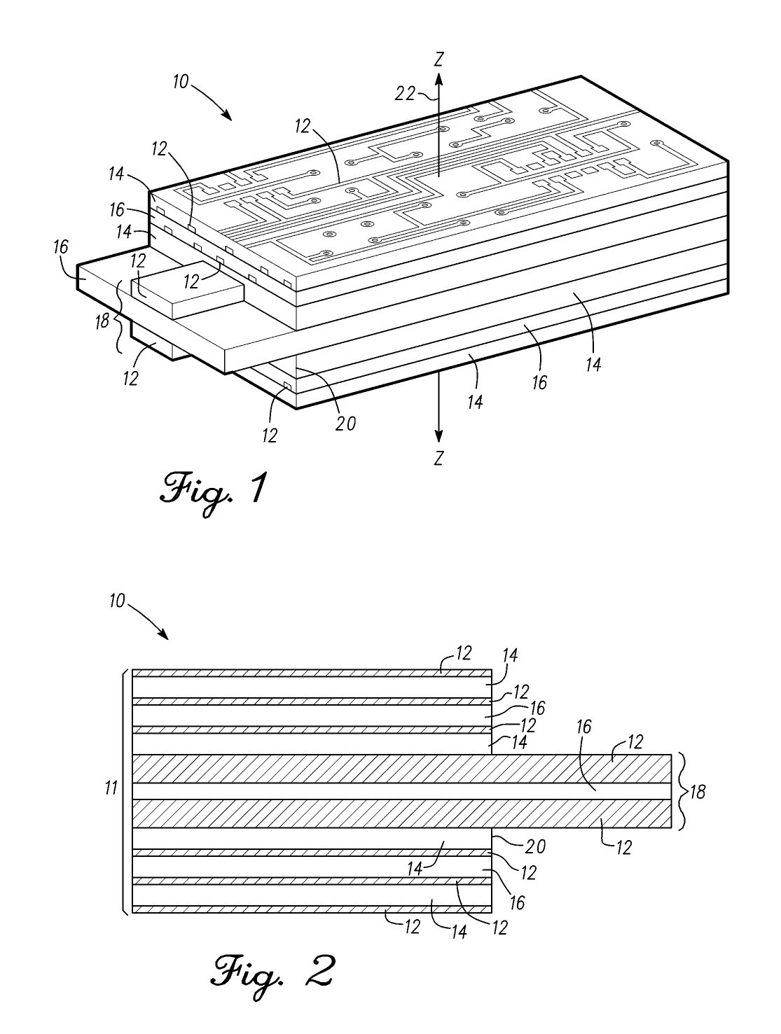

With respect to FIGS. 1 and 2, an exemplary printed circuit board 10, made in accordance with the teachings of the present disclosure, is schematically depicted. As best seen in FIG. 2, Printed circuit board 10 includes multiple adjacent electrically conductive layers 12 interleaved with a corresponding number of dielectric layers to form a body 11 having an alternate arrangement of electrically conductive layers 12 and dielectric layers. As used herein, the term “adjacent”, when used in conjunction with “electrically conductive layers”, refers to electrically conductive layers that are consecutive with one another notwithstanding the presence of an intervening dielectric layer.

In the illustrated embodiment, electrically conductive layers 12 may comprise any electrically conductive material including, for example, copper foil. As best seen in FIG. 1, the electrically conductive layers are etched or otherwise formed into electrically conductive pathways, known as traces.

In the illustrated embodiment, the dielectric layers include both epoxy resin prepreg layers 14 and substrate layers 16. Epoxy resin prepreg layers 14 are dielectric adhesive layers which serve to bond one substrate layer 16 to another to form body 11. Epoxy resin prepreg comes in sheets which cure upon the addition of pressure and temperature applied during lamination. That substrate layer 16, its traces, and epoxy resin prepreg layer 14 is then pressed against a second substrate layer 16. This process is repeated until a desired number of electrically conductive layers 12 have been assembled together. The epoxy resin prepreg layers 14 are then cured to form a solid dielectric structure which binds the multiple substrate layers 16 together.

Epoxy resin prepreg layer 14 may comprise any suitable adhesive including phenolic cotton paper, cotton paper and epoxy, woven glass and epoxy, matte glass and epoxy. Substrate layers 16 may comprise any suitable dielectric body including Teflon, and epoxy resin.

In the illustrated embodiment, two neighboring electrically conductive layers 12 (hereinafter, “neighboring pair 18”) protrude from an end 20 of body 11. As used herein, use of the term “neighboring” in connection with “electrically conductive layers 12” means the next consecutive electrically conductive layer 12 in the body 11 notwithstanding the presence of an intervening dielectric layer. Neighboring pair 18 is disposed in the approximate vertical center of body 11. As used herein, the term “vertical” refers to an orientation aligned with Z-axis 22 illustrated in FIG. 1. In other examples, neighboring pair 18 may protrude from any other position within body 11.

By configuring printed circuit board 10 such that neighboring pair 18 protrudes from an end of body 11, the electrically conductive layers 12 that comprise neighboring pair 18 are directly accessible. Components, such as bus bars, wires, leads, plugs, clips, electric connectors, and the like may be directly connected to the electrically conductive layers 12 of neighboring pair 18. By configuring printed circuit board 10 in this manner, the need to route electric current through via holes extending through body 11 to reach the electrically conductive layers 12 of neighboring pair 18 is eliminated.

There are many advantages to a printed circuit board that provides direct access to internally disposed electrically conductive layers 12. For example, the need for via holes in such a printed circuit board can be reduced or even eliminated. This, in turn, may reduce the cost and complication of fabricating printed circuit boards.

One non-limiting application for such a printed circuit board includes the carrying of relatively high electric currents. The higher the electric current, the thicker the electrically conductive layer must be. For example, a typical trace or electrically conductive layer carries electric current ranging from micro amps up to 100 Amps per trace and has a vertical thickness of approximately 0.0014 inches. One of ordinary skill in the art will refer to an electrically conductive layer having a thickness of 0.0014 inches as being a “one ounce” electrical copper (e.g., one ounce copper). By contrast, a trace or electrically conductive layer needed to carry an electric current of between 90 to 100 Amps requires a thickness of approximately 0.0168 inches, which is twelve times the thickness of a typical trace. This is referred to as a twelve ounce conductor (e.g., twelve ounce copper) by one of ordinary skill in the art. Because of existing constraints in the process of fabricating printed circuit boards, the thickened electrically conductive layers are disposed internally within body 11 instead of being disposed on an outer surface of the printed circuit board.

In the example illustrated in FIGS. 1 and 2, the electrically conductive layers 12 that comprise neighboring pair 18 are thicker than the other electrically conductive layers 12 of body 11 and are configured to carry relatively high electric currents. The protrusion of neighboring pair 18 from end 20 of body 11 greatly facilitates access to such thickened electrically conductive layers 12 and permits direct connection between the thickened electrically conductive layers and a carrier carrying the relatively high electric current. This configuration effectively eliminates the need to use via holes to access internally disposed thickened electrically conductive layers.

In the embodiment illustrated in FIG. 1, the electrically conductive layers 12 of neighboring pair 18 are vertically aligned with one another. This may be a useful configuration in applications where one trace of neighboring pair 18 carries positively charged electric current and the other trace of neighboring pair 18 carries negatively charged electric current. The close positioning and vertical alignment of the oppositely charged electric currents passing through neighboring pair 18 allows the two oppositely charged electric currents to counteract each other's tendency for induction. As a result, the overall induction within printed circuit board 10, as well as the overall induction within the device utilizing printed circuit board 10, is minimized by the illustrated vertically aligned configuration of the electrically conductive layers comprising neighboring pair 18.

There are many ways to fabricate printed circuit board 10 such that neighboring pair 18 protrudes from end 20 of body 11. In one non-limiting example, the individual electrically conductive layers 12 and the substrate layer 16 that make up neighboring pair 18 may have a greater length than the other electrically conductive layers and dielectric layers of body 11 such that neighboring pair 18 will naturally extend beyond end 20 when body 11 is assembled. In another non-limiting example, a portion of both the outer electrically conductive layers and the outer dielectric layers of printed circuit board 10 surrounding neighboring pair 18 proximate end 20 of body 11 may be mechanically stripped away to expose neighboring pair 18. Such processes as milling, grinding, shaving, and the like may be employed to expose neighboring pair 18. In still another non-limiting example, chemicals may be applied to the outer surfaces of body 11 to dissolve the outer electrically conductive and dielectric layers.

With respect to FIGS. 3-5, additional embodiments of printed circuit boards made in accordance with the teachings of the present disclosure are illustrated. With respect to FIG. 3, a printed circuit board 10′ is illustrated. Printed circuit board 10′ includes body 11 and substantially the same arrangement of electrically conductive layers and dielectric layers as is found in printed circuit board 10. Neighboring pair 18, however, does not protrude beyond an end of body 11. Rather, in printed circuit board 10′, access to neighboring pair 18 is obtained through openings 24. Each opening 24 extends from an outer surface 26 to a surface of each electrically conductive layer 12 of neighboring pair 18.

Opening 24 may have any suitable size and shape effective for providing access to neighboring pair 18. Unlike via holes, opening 24 is not plated or otherwise covered with an electrically conductive material and is not otherwise configured to carry electric current. A wire or other electrical connector may be inserted into opening 24 and pressed or otherwise positioned so as to electrically connect to one or both electrically conductive layers 12 of neighboring pair 18. Openings 24 may be disposed at any suitable location along a length of body 11, and may, in some embodiments, may merge with end 20 of body 11.

In the illustrated embodiment, two openings 24 are depicted, one each on opposite sides of printed circuit board 10′. In other non-limiting embodiments, only a single opening 24 may be formed to extend from one of the outer surfaces 26 to one of the electrically conductive layers 12 of neighboring pair 18. In another non-limiting embodiment, opening 26 may extend from one outer surface 26 through neighboring pair 18 to the other outer surface 26. In still other non-limiting embodiments, three or more openings may be provided to contact neighboring pair 18 at various locations along its length. Furthermore, while the illustrated embodiment depicts both openings 24 as being vertically aligned, it should be understood that openings 24 may be offset from one another in both a longitudinal and lateral direction, as desired.

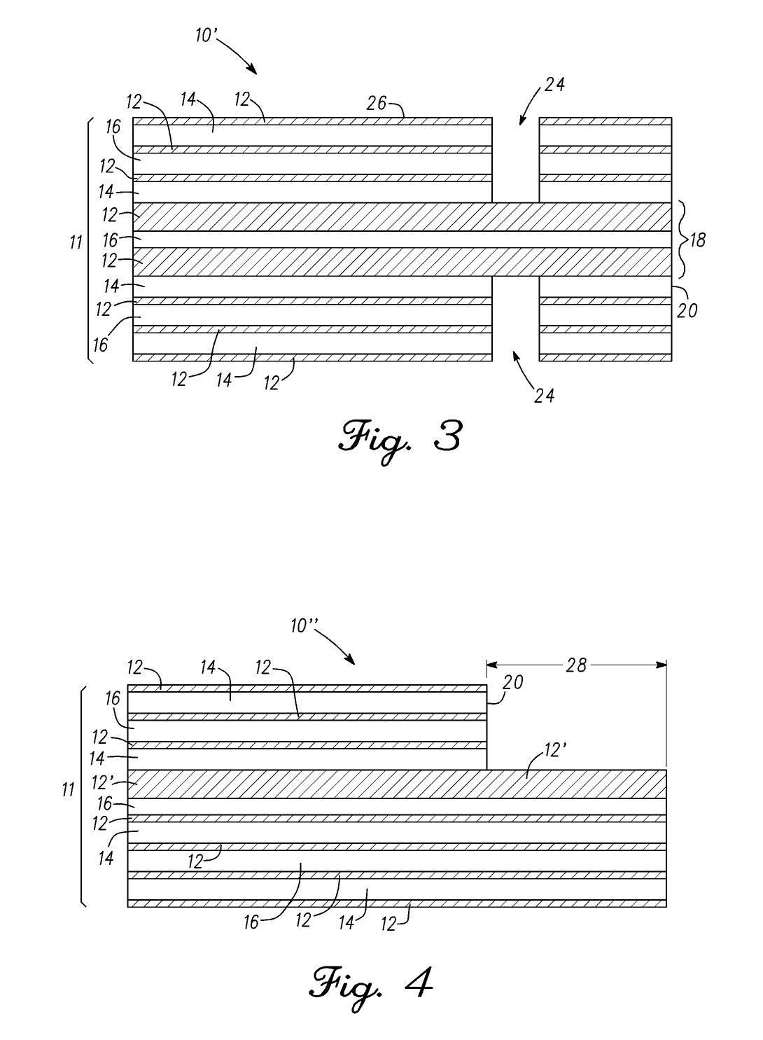

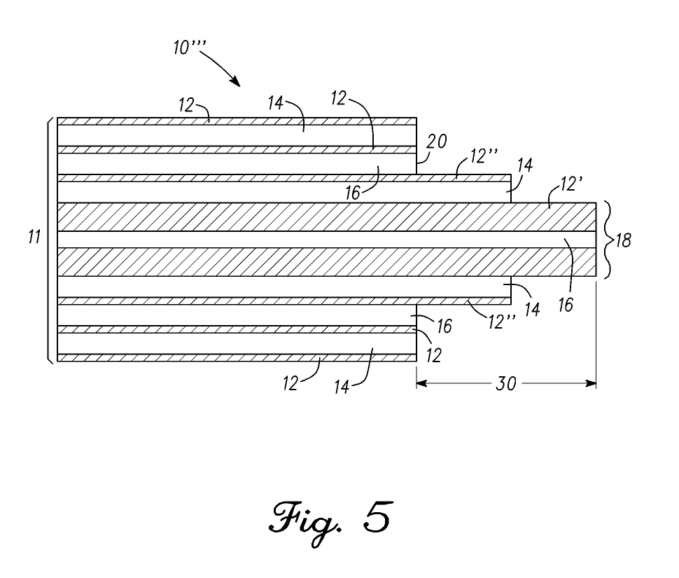

With respect to FIG. 4, a printed circuit board 10″ is illustrated. Printed circuit board 10″ is configured such that an extending portion 28 extends beyond end 20 of body 11. Such a configuration may be useful in circumstances when access to only a single internally disposed electrically conductive layer (electrically conductive layer 12′) is required. In the illustrated embodiment, electrically conductive layer 12′ is a thickened electrically conductive layer. In other embodiments, electrically conductive layer 12′ may have any suitable thickness.

The configuration shown in FIG. 4 may be obtained through the use of any suitable method of stripping away material from body 11 including, but not limited to, milling, grinding, and shaving, or through the use of unequal length components, or through the application of acids or solvents.

With respect to FIG. 5, a printed circuit board 10″′ is illustrated. The configuration of printed circuit board 10″′ provides access to four internally disposed electrically conductive layers 12 including electrically conductive layers 12′ and electrically conductive layers 12″. Portions of body 11 have been removed in a manner that leaves a step-like protrusion 30 extending from end 20. In the illustrated embodiment, step-like protrusion 30 comprises a two step structure. In other embodiments, step-like protrusion may be configured to have any desirable number of steps.

The configuration shown in FIG. 5 may be obtained through the use of any suitable method of stripping away material from body 11 including, but not limited to, milling, grinding, and shaving, or through the use of unequal length components, via the application of acids or solvents.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration in any way. Rather, the foregoing detailed description will provide those skilled in the art with a convenient road map for implementing the exemplary embodiment or exemplary embodiments. It should be understood that various changes can be made in the function and arrangement of elements without departing from the scope as set forth in the appended claims and the legal equivalents thereof.

What is claimed is:

1. A printed circuit board comprising:
a plurality of electrically conductive layers; and
a plurality of dielectric layers, each dielectric layer being interposed between adjacent conductive layers to form a body of alternate conductive layers and dielectric layers, at least one of the electrically conductive layers protruding beyond an end of the body.

2. The printed circuit board of claim 1, wherein the one of the electrically conductive layers is disposed in an approximate vertical center of the body.

3. The printed circuit board of claim 1, wherein the one of the electrically conductive layers has a thickness that is greater than a thickness of each other electrically conductive layer of the plurality of electrically conductive layers.

4. The printed circuit board of claim 3, wherein the one of the electrically conductive layers comprises an approximately 12 ounce layer of copper.

5. A printed circuit board comprising:
a plurality of electrically conductive layers; and
a plurality of dielectric layers, each dielectric layer being interposed between adjacent electrically conductive layers of the plurality of electrically conductive layers to form a body of alternate electrically conductive layers and dielectric layers,
wherein two neighboring electrically conductive layers internal to the body protrude beyond an end of the body.

6. The printed circuit board of claim 5 wherein the two neighboring electrically conductive layers are disposed in approximately a vertical center of the body.

7. The printed circuit board of claim 5 wherein the two neighboring electrically conductive layers each have a thickness that is greater than a thickness of each other electrically conductive layer of the plurality of electrically conductive layers.

8. The printed circuit board of claim 7 wherein the two neighboring electrically conductive layers each comprise an approximately 12 ounce layer of copper.

9. The printed circuit board of claim 5 wherein the two neighboring electrically conductive layers are substantially vertically aligned with one another throughout a portion of the body.

10. The printed circuit board of claim 9 wherein the two neighboring electrically conductive layers are substantially vertically aligned with one another at the end of the body.

11. The printed circuit board of claim 5 wherein an additional electrically conductive layer protrudes beyond the end of the body such that the additional electrically conductive layer and the two neighboring electrically conductive layers form a step-like arrangement protruding beyond the end of the body.

12. The printed circuit board of claim 5 wherein two additional electrically conductive layers protrude beyond the end of the body, one each on opposite sides of the two neighboring electrically conductive layers such that the two additional electrically conductive layers and the two neighboring electrically conductive layers form a step-like arrangement protruding beyond the end of the body.

13. The printed circuit board of claim 5, wherein the two neighboring electrically conductive layers are disposed in approximately a vertical center of the body, wherein the two neighboring electrically conductive layers each have a thickness that is greater than a thickness of each other electrically conductive layer of the plurality of electrically conductive layers, and wherein the two neighboring electrically conductive layers are substantially vertically aligned with one another throughout a portion of the body.

14. The printed circuit board of claim 13, wherein the two neighboring electrically conductive layers each comprise an approximately 12 ounce layer of copper, and wherein the two neighboring electrically conductive layers are substantially vertically aligned with one another at the end of the body.

15. A printed circuit board comprising:
a plurality of electrically conductive layers; and
a plurality of dielectric layers, each dielectric layer being interposed between adjacent electrically conductive layers of the plurality of electrically conductive layers to form a body of alternate electrically conductive layers and dielectric layers,
wherein a first non-electrically conductive opening extends from a first surface of the body to a first electrically conductive layer internal to the body.

16. The printed circuit board of claim 15 wherein the first electrically conductive layer has a thickness that is greater than a thickness of each other electrically conductive layer of the plurality of electrically conductive layers.

17. The printed circuit board of claim 16 wherein the first electrically conductive layer comprises an approximately 12 ounce layer of copper.

18. The printed circuit board of claim 15 wherein a second non-electrically conductive opening extends from a second surface of the body to a second electrically conductive layer internal to the body, the second surface being disposed on an opposite side of the body to the first surface.

19. The printed circuit board of claim 18 wherein the first electrically conductive layer and the second electrically conductive layer each have a thickness that is greater than a thickness of each other electrically conductive layer of the plurality of electrically conductive layers.

20. The printed circuit board of claim 19 wherein the first electrically conductive layer and the second electrically conductive layer each comprise an approximately 12 ounce layer of copper.
